(19) United States
(12) Patent Application Publication
(10) Pub. No.: US 2008/0264340 A1
(43) Pub. Date: Oct. 30, 2008

(54) MOVING INTERLEAVED SPUTTER CHAMBER SHIELDS

(75) Inventors: Robert Martinson, Palo Alto, CA (US); Norman Bourdon, Sunnyvale, CA (US); Kwok Fai Lai, Pal Alto, CA (US); Dhairya Shrivastava, San Jose, CA (US); Paul Shufflebothan, San Jose, CA (US)

Correspondence Address: LAW OFFICE OF DELIO & PETERSON, LLC., 121 WHITNEY AVENUE, 3RD FLLOR, NEW HAVEN, CT, 06510, US

(73) Assignee: Novellus Systems, Inc., San Jose, CA (US)

(21) Appl. No.: 12/169,238

(22) Filed: Jul. 8, 2008

Related U.S. Application Data
(63) Continuation of application No. 10/823,355, filed on Apr. 12, 2004.

(51) Int. Cl. C23C 16/00

(52) U.S. Cl. 118/715

(57) ABSTRACT

A shielding system for a physical vapor deposition chamber having a sputter target above the pedestal. The shielding system comprises a pedestal shield attachable to the pedestal and movable therewith. The pedestal shield surrounds and extends outward from the pedestal toward the chamber side or lower walls. The system also comprises a sidewall shield adapted to extend substantially around and within the chamber sidewalls, and downward from an upper portion thereof. The sidewall shield has a lower end extending inward and disposed adjacent the pedestal shield upper portion when the pedestal is in the raised position. The pedestal shield and sidewall shield cooperate, when the pedestal is in the raised position, to prevent line-of-sight deposition transmission from the sputter target to the side and lower walls of the deposition chamber.

### BACKGROUND OF THE INVENTION

1. Field of the Invention

This invention relates to devices for containing unwanted deposition (over-spray) in a deposition chamber used for processing semiconductor wafers and, more particularly, to a passive shielding device positioned inside a deposition chamber used for processing semiconductor wafers which shields deposition from the vacuum chamber and can be removed and replaced.

2. Description of Related Art

In the fabrication of semiconductor devices, a deposition chamber is used to deposit metal films on wafer surfaces using physical vapor deposition (PVD) techniques. The PVD apparatus is generally termed a sputtering apparatus and a wafer is placed inside a vacuum chamber within the deposition chamber, and is positioned on a wafer holder or pedestal. The wafer holder or pedestal is normally supported on the bottom wall of the vacuum chamber by insulating means, and the vacuum chamber is further equipped with a sputtering gas inlet which is connected to a gas supply such as argon or other inert gases. A gas outlet is also provided in the vacuum chamber and it is connected to an evacuation pump to maintain the desired pressure within the chamber during the metal deposition process.

A target of the suitable metallic material is mounted to the top wall of the chamber and is electrically connected to the negative terminal of a power supply. During the process the target is energized and metal particles are ejected from the target and coat the wafer and other portions of the chamber interior. Deposition of the metal on unwanted areas of the chamber walls can result in problems, including particles on the wafer. Thus, a chamber shield is used to protect portions of the chamber interior from undesired deposition of the metallic material. The wafer holder in combination with the chamber shield protects the lower chamber cavity of the PVD chamber from the metal particles ejected from the target during the deposition process.

A typical PVD chamber shield is cylindrically shaped and has top extensions adjacent to the edges of the metal target and bottom extensions that overlap the bottom edge of the wafer holder. The conventional chamber shield made by the assignee of this invention consists of from six to nine components, most of which are static and require significant surface area to cover the internal surfaces of the chamber. Additionally, if the shield has a large surface area, additional process time is required for pumping and bake out. Due to complex shapes, some of these shields require costly manufacturing techniques. Since there are a large number of parts in the shield kit, considerable effort is required to install and remove the shield.

### SUMMARY OF THE INVENTION

Bearing in mind the problems and deficiencies of the prior art, it is therefore an object of the present invention to provide an improved shield system for shielding the interior of deposition chambers, particularly for PVD systems.

It is another object of the present invention to provide a deposition chamber shield system that minimizes the number of shield components.

A further object of the invention is to provide a deposition chamber shield system that is less costly to manufacture.

It is yet another object of the present invention to provide a deposition chamber shield system that is easier to install, maintain and remove.

Still other objects and advantages of the invention will in part be obvious and will in part be apparent from the specification.

It is another object of the present invention to provide a shield system that provides variable wafer holder vertical positions without parts that touch or otherwise come into contact with each other.

The above and other objects, which will be apparent to those skilled in art, are achieved in the present invention which is directed to a shielding system for a physical vapor deposition chamber, wherein the chamber has a pedestal movable between a lowered loading and unloading position and a raised deposition processing position and is surrounded by chamber interior lower, side and upper walls, with the chamber further including a sputter target above the pedestal. The shielding system comprises a pedestal shield attachable to the pedestal and movable therewith between the lowered and raised positions. The pedestal shield surrounds and extends outward from the pedestal toward the chamber side or lower walls. The system also comprises a sidewall shield adapted to extend substantially around and within the chamber sidewalls, and downward from an upper portion thereof. The sidewall shield has a lower end extending inward and disposed adjacent the pedestal shield upper portion when the pedestal is in the raised position. The pedestal shield and sidewall shield cooperate, when the pedestal is in the raised position, to prevent line-of-sight deposition transmission from the sputter target to the side and lower walls of the deposition chamber.

When the pedestal is in the raised position, the pedestal shield and sidewall shield may further cooperate to prevent line-of-sight or gas-scattered transmission deposition from sides of the pedestal shield facing toward the chamber upper walls to the side and lower walls of the deposition chamber.

The sidewall shield lower end may be disposed below and outward of an upper surface of the pedestal when the pedestal is in the raised position.

The pedestal shield may have an upper portion surrounding the pedestal and a lower portion extending downward therefrom around the pedestal toward the chamber lower wall, and an outward portion extending away from the lower portion. The sidewall shield may have a lower end disposed below and outward of the pedestal shield upper portion and inward of the pedestal shield outward portion when the pedestal is in the raised position. The sidewall shield may further have an outward portion between the chamber sidewall and the sidewall shield lower end disposed outward of the pedestal shield outward portion when the pedestal is in the raised position. The sidewall shield may also have an outward portion between the chamber sidewall and the sidewall shield lower end disposed outward of the pedestal shield outward portion when the pedestal is in the raised position.

Alternatively, the pedestal shield has an upper portion surrounding the pedestal, a lower portion extending downward therefrom around the pedestal toward the chamber lower wall and an outward portion extending upward and away from the lower portion, and the sidewall shield has a lower end disposed below and outward of the pedestal shield upper portion and inward of the pedestal shield outward portion when the pedestal is in the raised position.

The shielding system sidewall shield lower end may be disposed above the pedestal shield when the pedestal is in the raised position and the pedestal shield extends outward from the pedestal toward the chamber sidewalls and below the sidewall shield lower end.

Also, the pedestal shield may have an upper portion surrounding the pedestal and a lower portion extending downward therefrom around the pedestal toward the chamber lower wall, and the sidewall shield may have an extension to the lower end thereof extending downward below the pedestal shield lower portion, and an inward portion extending upward from the extension, such that the pedestal shield lower portion is between the sidewall shield lower end extension and sidewall shield inward portion.

In another embodiment, the pedestal shield may have an upper portion surrounding the pedestal and a lower portion extending downward therefrom around the pedestal toward the chamber lower wall. In this embodiment, the shielding system further includes a bottom wall shield having a lower portion extending along the chamber lower wall, and inward and outward portions extending upward from the bottom wall shield lower portion. The bottom wall shield inward portion extends inward of the platform shield lower portion and the bottom wall shield outward portion extends outward of the platform shield lower portion.

Preferably, the sidewall shield lower end, or at least a portion thereof, is above the pedestal, when the pedestal is in the lowered position, a distance sufficient to permit a wafer to be horizontally loaded onto the pedestal. The pedestal and sidewall shields are preferably adapted to avoid contact with each other in the raised and lowered pedestal positions.

In another aspect, the present invention is directed to a method of shielding a physical vapor deposition chamber. The chamber has a pedestal movable between a lowered loading and unloading position and a raised deposition processing position and is surrounded by chamber interior lower, side and upper walls. The chamber further includes a sputter target above the pedestal. The method comprises initially providing a shielding system having a pedestal shield secured to the pedestal and movable therewith between the lowered and raised positions. The pedestal shield surrounds and extends outward from the pedestal toward the chamber side or lower walls. There is also provided a sidewall shield extending substantially around and within the chamber sidewalls, and downward from an upper portion thereof. The sidewall shield has a lower end extending inward and disposed adjacent the pedestal shield upper portion when the pedestal is in the raised position. The method then includes moving the pedestal to the lowered position in the chamber such that the sidewall shield lower end is above the pedestal a distance sufficient to permit a wafer to be horizontally loaded onto the pedestal. The method further includes moving the pedestal to the raised position, the pedestal shield and sidewall shield cooperating to prevent line-of-sight or gas-scattered transmission of deposition from the sputter target to the side and lower walls of the deposition chamber.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 is a top plan view of the preferred sidewall and pedestal shield system of the present invention mounted in a PVD chamber.

FIG. 2 is a side elevational view, in cross-section, of the sidewall and pedestal shield system of FIG. 1, with the pedestal in a lowered, wafer loading and unloading position.

FIG. 3 is a side elevational view, in cross-section, of the sidewall and pedestal shield system of FIG. 1, with the pedestal in a raised, wafer processing position.

FIG. 4 is a close-up view, in cross-section, of the interlocking sidewall and pedestal shields of FIG. 3.

FIG. 5 is a side elevational view, in cross-section, of a modification of the sidewall and pedestal shield system of FIGS. 1-4, with the pedestal in the lowered position.

FIG. 6 is a side elevational view, in cross-section, of the sidewall and pedestal shield modification of FIG. 5, with the pedestal in the raised position.

FIG. 7 is a side elevational view, in cross-section, of another modification of the sidewall and pedestal shield system of FIGS. 1-4, with the pedestal in the lowered position.

FIG. 8 is a side elevational view, in cross-section, of the sidewall and pedestal shield modification of FIG. 7, with the pedestal in the raised position.

FIG. 9 is a side elevational view, in cross-section, of a modification of the sidewall and pedestal shield system of FIGS. 7 and 8, with the pedestal in the lowered position.

FIG. 10 is a side elevational view, in cross-section, of the sidewall and pedestal shield modification of FIG. 9, with the pedestal in the raised position.

FIG. 11 is a side elevational view, in cross-section, of a modification of the sidewall and pedestal shield system of FIGS. 9 and 10, with the pedestal in the lowered position.

FIG. 12 is a side elevational view, in cross-section, of the sidewall and pedestal shield modification of FIG. 11, with the pedestal in the raised position.

FIG. 13 is a side elevational view, in cross-section, of another modification of the sidewall and pedestal shield system of FIGS. 9 and 10, with the pedestal in the lowered position.

FIG. 14 is a side elevational view, in cross-section, of the sidewall and pedestal shield modification of FIG. 13, with the pedestal in the raised position.

FIG. 15 is a side elevational view, in cross-section, of a further modification of the shield system of FIGS. 1-4, where the shield system has three basic parts, with the pedestal in the lowered position.

FIG. 16 is a side elevational view, in cross-section, of the shield modification of FIG. 15, with the pedestal in the raised position.

FIG. 17 is a side elevational view, in cross-section, of another modification of the shield system of FIGS. 1-4, where the shield system has three basic parts, with the pedestal in the lowered position.

FIG. 18 is a side elevational view, in cross-section, of the shield modification of FIG. 17, with the pedestal in the raised position.

FIG. 19 is a side elevational view, in cross-section, of another modification of the shield system of FIGS. 1-4, with the pedestal in the lowered position.

FIG. 20 is a side elevational view, in cross-section, of the shield modification of FIG. 19, with the pedestal in the raised position.

### DESCRIPTION OF THE PREFERRED EMBODIMENT(S)

In describing the preferred embodiment of the present invention, reference will be made herein to FIGS. 1-20 of the drawings in which like numerals refer to like features of the invention.

The present invention provides shielding system and method of shielding the interior walls of a sputter or PVD chamber using moving interleaved shielding segments. A first embodiment of the shield system of the present invention is depicted in FIGS. 1-4. In FIGS. 1, 2 and 3, a PVD deposition chamber 20 has an otherwise conventional vacuum valve or gate system 38 which permits wafers to be loaded into and removed from the chamber interior 22. The chamber interior has a central axis 33 and is bounded by lower wall 36, sidewall 34 and upper wall 32, and defines a generally cylindrical interior volume. Wafer holder or pedestal 30 is secured to movable support 28 along the central axis and may be positioned between a wafer loading and unloading position (FIG. 2) and a raised, processing position (FIG. 3) in which the wafer 29 is proximate to a sputter target 26 secured at the top interior portion of chamber 20. To define a smaller process volume 24 in the raised, processing position, sidewall and pedestal shield segments or portions are provided to prevent deposition transmission from the sputter target to the side and lower walls of the deposition chamber.

The sidewall shield extends substantially around and within the chamber sidewalls, and comprises downwardly extending vertical portion 40 and inwardly extending portion 46 at the lower end thereof, and an arcuate section 44 extending initially upward from the inward extending section 46, and then curving downward to a lower and inner end or edge 42, proximate to, but spaced from, the outer edge of circular pedestal 30. The sidewall shield may be attached or otherwise secured to the chamber interior by resting on a surface feature provided by the chamber. In the sidewall shield, both the inwardly extending portion 46 and the inner end 42 extend downward below the plane of the top surface of wafer holder or pedestal 30 when the pedestal is in the raised position. As used herein, the terms inward and outward are with respect to the central axis 33 of the chamber (FIG. 1).

The pedestal shield extends substantially around to surround pedestal 30 and is movable therewith. The pedestal shield comprises an inner portion 50 extending outwardly toward the chamber side walls, an arcuate portion 54 extending initially downward from portion 50, toward the chamber lower wall, and then curving upward and terminating in upward and outward edge or end 52. In the embodiment shown, substantially all portions of the pedestal shield are below the plane of the top surface of pedestal, and substantially all portions of the sidewall shield are above the gate 38 opening. This provides the particular advantage in that the components do not interfere with the loading and unloading of the wafer into and out of the deposition chamber. As shown in FIG. 2, when in the lowered loading/unloading position of the wafer pedestal, a wafer may be moved horizontally between gate 38 and the top surface of the pedestal 30 without interference from either the sidewall or pedestal shield components.

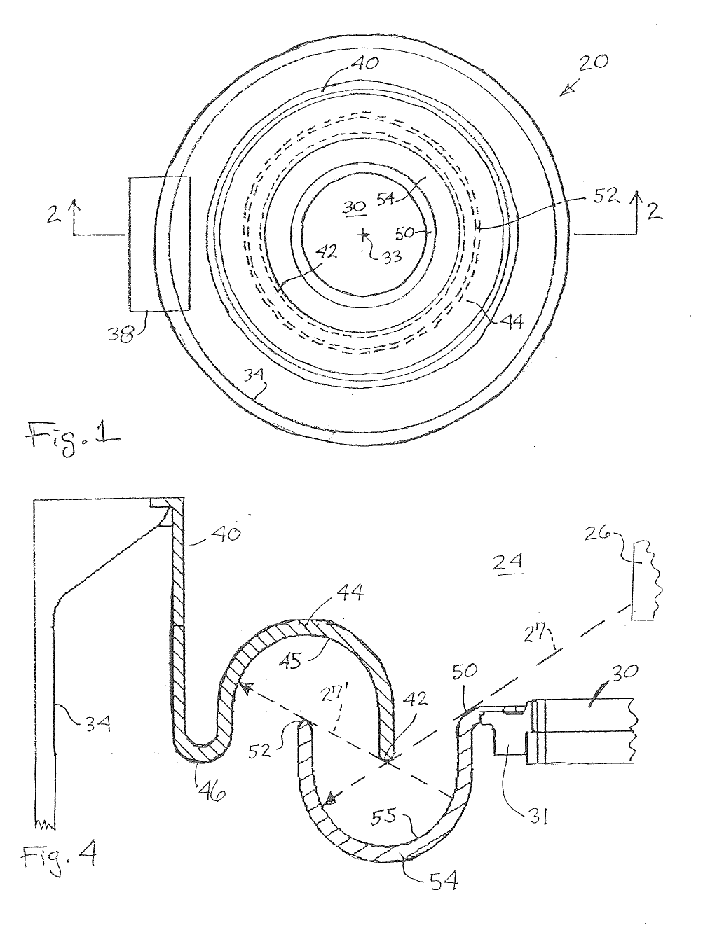

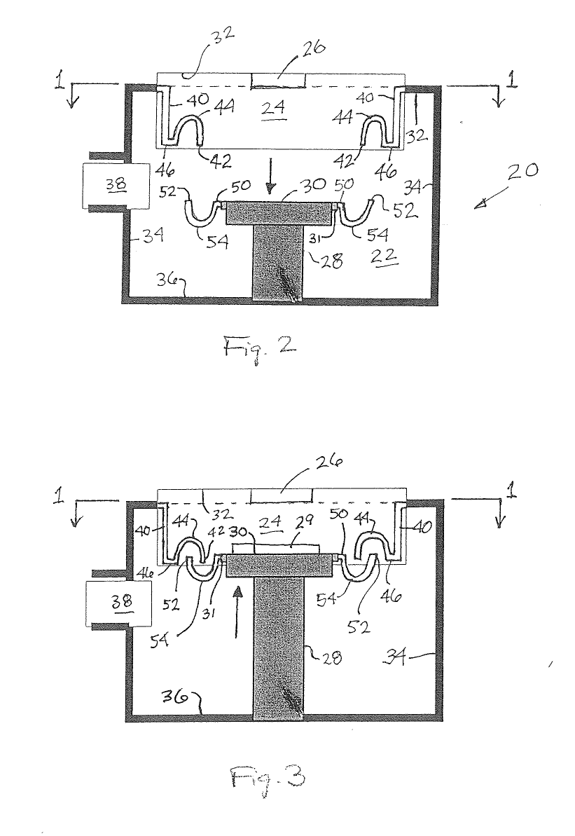

As shown more clearly in the close-up view in FIG. 4, the inner portion 50 of the pedestal shield is attached to the pedestal by resting on, or being secured to the pedestal isolator ring portion 31 of pedestal 30. Other attachment methods may be used to secure the pedestal shield to the pedestal, such as securing with screws or other mechanical connection. Sidewall shield arcuate section 44 and pedestal shield arcuate portion 54 interlock without contacting one another so that the lower inward end 42 of the sidewall shield is disposed outward of the pedestal shield inward and upper portion 50, and inward of the pedestal shield outward portion 52. When in the raised position as shown, pedestal shield outward portion 52 is disposed outward of sidewall shield inner portion 42, and inward of sidewall shield outer portions 40 and 46, while the sidewall shield vertical portion 40 is outward of the pedestal shield, and between the pedestal shield outward end 52 and the chamber side wall 34. Sidewall shield inward end 42 is also lower than the pedestal shield inner portion 50 and outward end 52. This prevents not only line-of-sight transmission of deposition from target 26 to the chamber sidewalls 34, as shown by ray 27 hitting the upward facing side 55 of the pedestal shield, but this configuration also prevents secondary gas-scatter ray transmission from the pedestal shield to the chamber sidewalls as shown by secondary ray 27′ emitted from the upwardly facing side 55 of the pedestal shield and hitting the lower facing side 45 of the sidewall shield.

The sidewall and pedestal shield components of the present invention may be made from any material typically used in PVD deposition chamber shielding, for example stainless steel or aluminum.

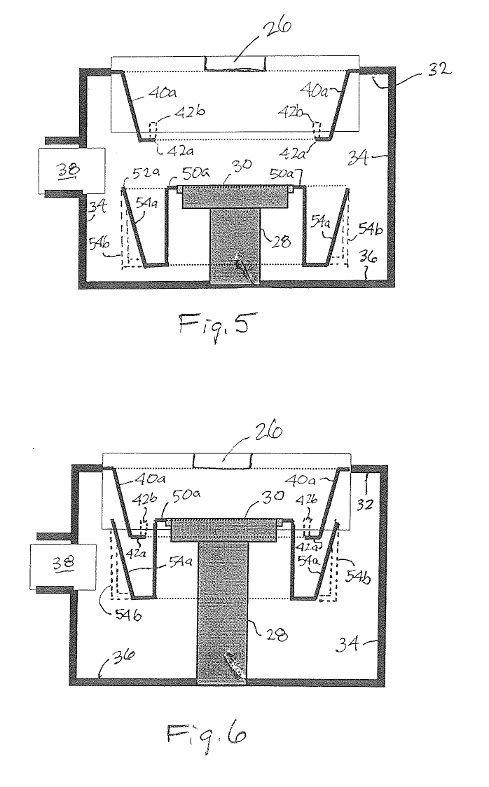

Further embodiments of the present invention are depicted in FIGS. 5 and 6, which modify the embodiment shown in FIGS. 1-4. In these embodiments the sidewall shield may have an inwardly and downwardly sloping portion 40a which extends from chamber top wall 32. Sidewall shield portion 42a extends inward from the lower end of portion 40a, and optionally includes an upward extending lip or end 42b. The pedestal shield has an inner portion 50a attached to the pedestal or pedestal isolation ring, and a lower and outwardly extending portion that either extends straight downward, horizontally outward and upward at an angle (54a), or that extends straight downward, horizontally outward and straight upward (54b). The transitions between the various portions of the pedestal and sidewall shields in the embodiments of FIGS. 5 and 6 are sharp, rather than curving as in the embodiment of FIGS. 1-4. It should be understood that in the embodiments described herein, which are seen primarily in elevational cross-section, the pedestal and sidewall shield have circular configurations as seen in top plan view (e.g., FIG. 1 of the first embodiment), and are generally symmetrical with respect to the chamber central axis 33. In a manner similar to the embodiment of FIGS. 1-4, the embodiments of FIGS. 5 and 6 have the inner portion of the sidewall shield 42a nestled within the inner and outer portions 54a or 54b of the pedestal shield, and lower than the upper portions of the pedestal shield, to prevent line-of-sight and gas-scatter transmission of deposition from the sputter target to the chamber side walls when the pedestal is in the raised position (FIG. 6). As before, when in the lowered pedestal position the sidewall and pedestal shields permit free and unhindered loading and unloading of the wafer to and from the pedestal.

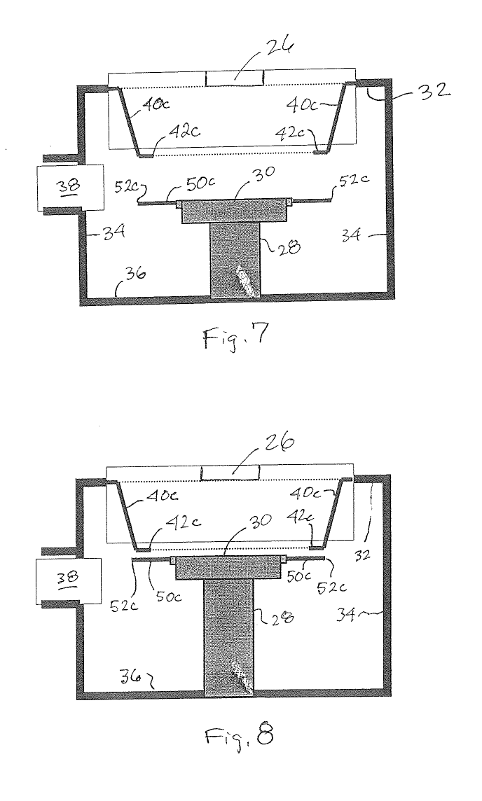

Another modification of the embodiment of FIGS. 1-4 is shown in FIGS. 7 and 8. The sidewall shield has extending from chamber upper wall an inwardly and downwardly sloping portion 40c, which has a horizontally extending portion that ends at an inward end 42c above the gate 38 opening. The pedestal shield has a flat, horizontal portion 50c that extends from the pedestal to an outward end 52c. When in the pedestal raised position (FIG. 8), the inward end 42c of the sidewall shield is above and inward of the pedestal shield outward end 52c, and in sufficiently close proximity to the pedestal shield to prevent line-of-sight transmission from the sputter target 26 to the chamber side walls 34.

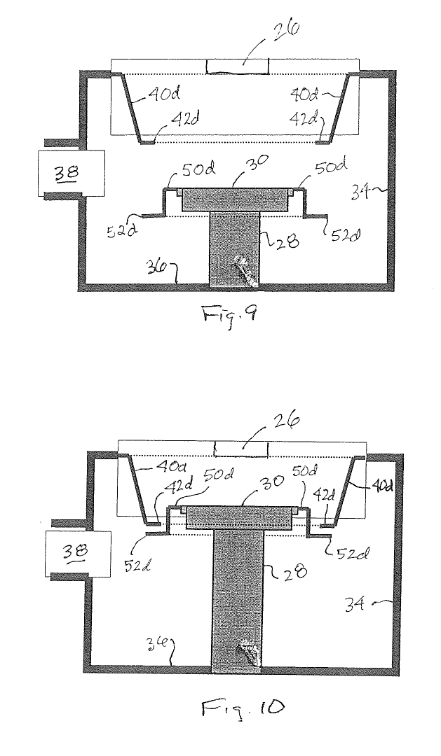

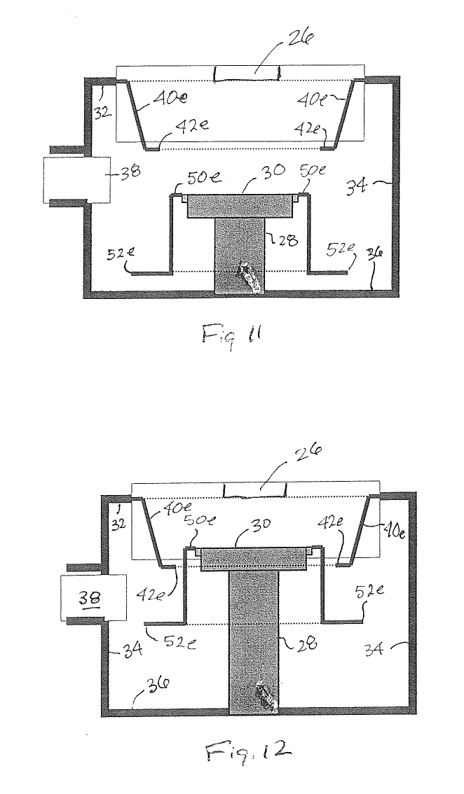

FIGS. 9 and 10 depict a modification of the embodiment of FIGS. 7 and 8. As before, the sidewall shield has an inwardly and downwardly sloping portion 40d, and a horizontally inwardly extending end 42d. Sidewall end 42d, however, extends below the plane of the top surface of pedestal 30. The pedestal shield has attached an outwardly and downwardly extending portion 50d, and a horizontally outwardly extended end 52d, the latter of which is below and outward of sidewall shield end 42d when the pedestal is in the raised position (FIG. 10). The ends of the pedestal and sidewall shields are again in sufficiently close proximity in FIG. 10 to prevent line-or-sight transmission from target 26 to the chamber side walls. FIGS. 11 and 12 present a modification of the embodiment of FIGS. 9 and 10. Again, the sidewall shield has an inwardly and downwardly sloping portion 40e, and a horizontally inwardly extending end 42e, comparable to that of FIGS. 9 and 10. However, the pedestal shield has attached a downwardly extending portion that extends considerably farther downward toward the chamber lower wall 36, and a horizontally extending outward end 52e that is considerably closer to chamber side walls 34. The sidewall inner end 42e is positioned and the pedestal shield portions are of length sufficient to again prevent line-of-sight transmission from the sputter target 26 to the chamber side walls 34.

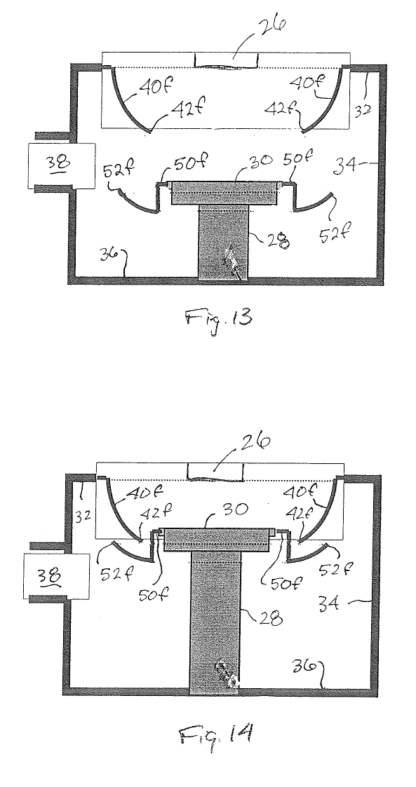

Yet another modification of the pedestal and sidewall shield system of FIGS. 9 and 10 is shown in FIGS. 13 and 14. Instead of the previous configuration, the sidewall shield has a curved inwardly and downwardly extending portion 40f, ending in a lower and inward end 42f that again is below the upper plane of pedestal 30, and in close proximity to the side of the pedestal. The pedestal shield has attached an outwardly and downwardly extending portion 50f, and an outwardly and upwardly curving end 52f extending therefrom to a position below the pedestal upper surface plane. The lengths and configuration of sidewall shield end 42f and pedestal shield end 52f are such, and pedestal shield end 52f is at approximately the same vertical level as sidewall shield end 42f, as to prevent line-of-sight transmission between target 26 and chamber side walls 34 when the pedestal is in the raised, processing position.

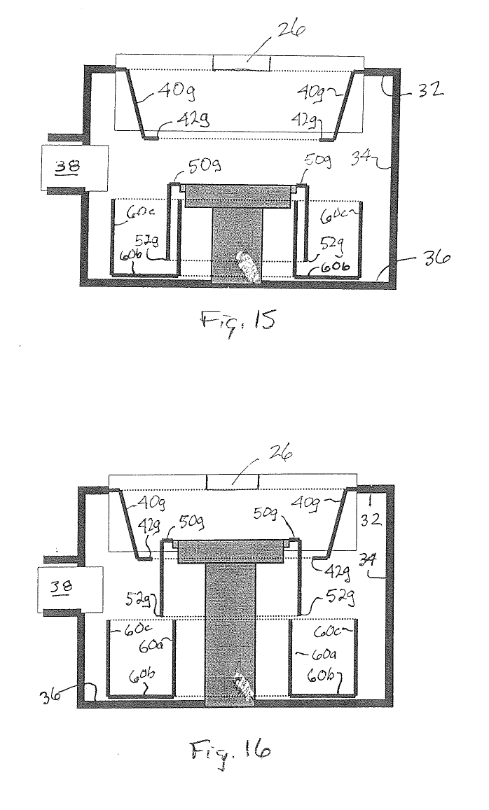

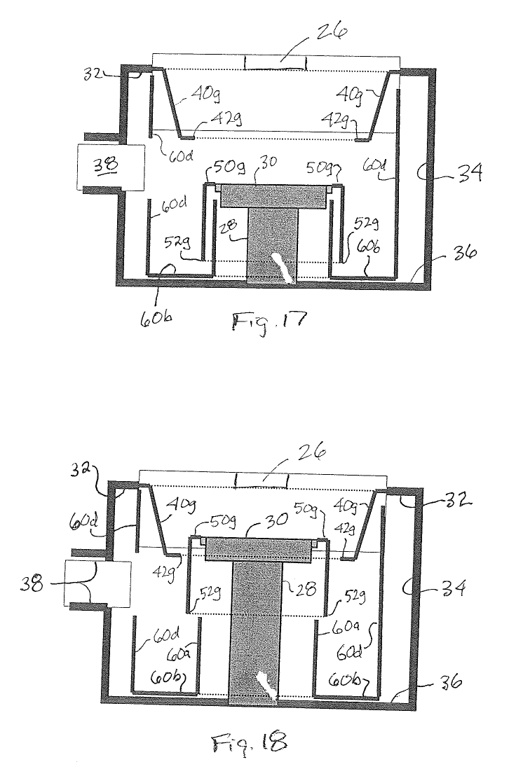

Shield system embodiments having three basic parts are depicted in FIGS. 15-18. In the embodiments shown in FIGS. 15 and 16, and in FIGS. 17 and 18, the sidewall shield has an inwardly and downwardly sloping portion 40g, and a horizontally inwardly extending end 42g, similar to that of the FIG. 9/10 embodiment, in which the lower and inward end 42g is below the upper plane of, and in close proximity to the side of, the pedestal. In both the FIG. 15/16 embodiment, and the FIG. 17/18 embodiment, the pedestal shield has a horizontally outward extending portion 50g, whose inward end is attached to the pedestal, and a vertically downward extending portion (inward of sidewall shield end 42g) ending in a lower end 52g. In the embodiment of FIGS. 15 and 16, a third, bottom or lower wall component of the shield system rests over and is preferably attached to chamber lower wall 36, and protects at least a portion of the chamber side walls. The lower wall shield has an annular, flat horizontal portion 60b, and inner vertically upwardly extending portion 60a, and an outer, vertically upwardly extending portion 60c. The upper ends of vertical portions 60a, 60c are at approximately the same height, but slightly below, the height of pedestal shield lower end 52g when the pedestal is in the raised position (FIG. 16). The inner vertical portion 60a is inward of the pedestal shield lower end 52g, to avoid contact when the pedestal is in the lowered position (FIG. 15). The lower wall shield may be attached or otherwise secured to the chamber interior by resting on, or being mechanically secured to the chamber lower surface.

The embodiment of FIGS. 17 and 18 is similar to that of FIGS. 15 and 16, except that the lower wall component of the shield system has an outer vertical portion that extends upward to the proximity of chamber upper wall 32 and shields essentially all of the chamber side walls 34. To permit the loading and unloading of a wafer on the pedestal, vertical portion 60d has on one side (left as shown) an opening conforming to that of gate 38. In the raised, processing position the configurations of the pedestal, sidewall and lower wall shield components in the embodiments of FIGS. 15-18 prevent line-of sight target transmission to the chamber side and lower walls.

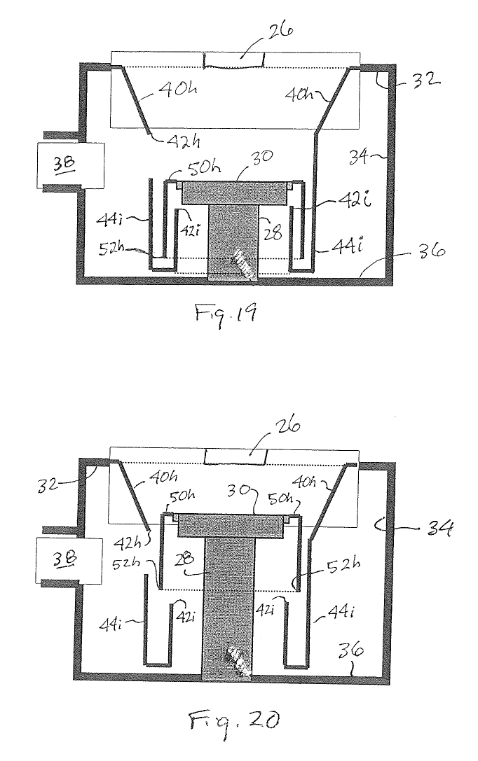

Yet another embodiment of the shield system of the present invention is depicted in FIGS. 19 and 20. The pedestal shield is similar to that of the embodiments of FIGS. 15/16 and 17/18 wherein it has a horizontally outward extending portion 50h, whose inward end is attached to the pedestal, and a vertically downward extending portion ending in a lower end 52g. The sidewall shield has an inwardly and downwardly sloping portion 40h, the lower end of which is adjacent the sides of pedestal 30 and below the plane of the upper surface when the pedestal is in the raised position (FIG. 20), and a lower portion 44i that extends vertically downward outward of pedestal shield lower end 52h, horizontally inward proximate to the chamber lower wall 36, and then a vertical upward portion 41i positioned inward of pedestal shield lower end 52h. Pedestal shield lower end 52h is nested within the sidewall shield lower portion vertical sections when the pedestal is in the lowered position (FIG. 19).

The shielding system of the present invention thus contains the deposition in the process volume of the chamber with a minimum number of components that is generally less costly to manufacture than complex prior art shielding systems. The present invention in general employs an interleaving design that permits good vacuum conductance while blocking the deposition from accumulating on the chamber walls. The interleaving shielding system comprises two or more shields that move together to form an interleaved containment volume before the deposition process commences to prevent leakage of the sputtered material onto the chamber wall. In view of the minimum number of components and shield configuration, removal and installation of the shields is relatively easy.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

1. A shielding system for a physical vapor deposition chamber, the chamber having a pedestal movable between a lowered loading and unloading position and a raised deposition processing position and surrounded by chamber interior lower, side and upper walls, the chamber further including a sputter target above the pedestal, the shielding system comprising:
a pedestal shield attachable to the pedestal and movable therewith between the lowered and raised positions, the pedestal shield having an outwardly and downwardly extending portion surrounding and extending from the pedestal toward the chamber lower walls and an outwardly and upwardly curving end extending toward the chamber side walls; and
a sidewall shield adapted to extend substantially around and within the chamber sidewalls, and downward from an upper portion thereof, the sidewall shield having a curved inwardly and downwardly extending portion with a lower end extending inward and disposed below a pedestal upper surface plane and adjacent the pedestal shield upper portion when the pedestal is in the raised position, the sidewall shield lower end being above the pedestal when the pedestal is in the lowered position a distance sufficient to permit a wafer to be horizontally loaded onto the pedestal, the pedestal shield and sidewall shield cooperating, when the pedestal is in the raised position, to avoid contact with each other and prevent line-of-sight deposition transmission from the sputter target to the side and lower walls of the deposition chamber.

2-19. (canceled)

20. A method of shielding a physical vapor deposition chamber, the chamber having a pedestal movable between a lowered loading and unloading position and a raised deposition processing position and surrounded by chamber interior lower, side and upper walls, the chamber further including a sputter target above the pedestal, the method comprising:
providing a shielding system having a pedestal shield secured to the pedestal and movable therewith between the lowered and raised positions, the pedestal shield having an outwardly and downwardly extending portion surrounding and extending from the pedestal toward the chamber lower walls and an outwardly and upwardly curving end extending toward the chamber side walls, and a sidewall shield extending substantially around and within the chamber sidewalls, and downward from an upper portion thereof, the sidewall shield having a curved inwardly and downwardly extending portion with a lower end extending inward;
moving the pedestal to the lowered position in the chamber such that the sidewall shield lower end is above the pedestal a distance sufficient to permit the wafer to be horizontally loaded onto the pedestal;
while in the lowered position, loading the wafer onto the pedestal; and
moving the pedestal to the raised position whereby the sidewall shield lower end is disposed below a pedestal upper surface plane and adjacent the pedestal shield upper portion, the pedestal shield and sidewall shield avoiding contact with each other and cooperating to prevent line-of-sight or gas-scattered transmission of deposition from the sputter target to the side and lower walls of the deposition chamber.
